(19) United States
(12) Patent Application Publication
(10) Pub. No.: US 2008/0006885 A1
(43) Pub. Date: Jan. 10, 2008

(54) SEMICONDUCTOR INTEGRATED CIRCUIT DEVICE AND METHOD OF MANUFACTURING

(76) Inventors: Fumitaka ARAI, Yokohama-shi (JP); Makoto Sakuma, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/853,544

(22) Filed: Sep. 11, 2007

Related U.S. Application Data
(63) Continuation of application No. PCT/JP05/17095, filed on Sep. 9, 2005.

(30) Foreign Application Priority Data
Mar. 11, 2005 (JP) 2005-069123

(51) Int. Cl. H01L 29/76; H01L 21/82

(52) U.S. Cl. 257/390; 257/510; 438/129; 257/E29.129

(57) ABSTRACT

A semiconductor integrated circuit device comprises an insulated-gate field-effect transistor, the insulated-gate field-effect transistor comprising a device isolation insulating film that is provided to extend from an inside of a semiconductor substrate and to project from an upper surface of the semiconductor substrate, and defines a device region on the semiconductor substrate, a gate insulation film that is provided on the device region, a gate electrode that is provided on the gate insulation film, source/drain regions that are provided in the semiconductor substrate on both sides of the gate electrode, an insulation layer that is provided on the gate electrode, and a contact line that penetrates the insulation layer and is put in contact with the gate electrode.

### CROSS REFERENCE TO RELATED APPLICATIONS

This is a Continuation Application of PCT Application No. PCT/JP2005/017095, filed Sep. 9, 2005, which was published under PCT Article 21(2) in English.

This application is based upon and claims the benefit of priority from prior Japanese Patent Application No. 2005-069123, filed Mar. 11, 2005, the entire contents of which are incorporated herein by reference.

### BACKGROUND OF THE INVENTION

1. Field of the Invention

The present invention relates to a semiconductor integrated circuit device and a method of manufacturing the same. For example, the invention relates to a high-voltage insulated-gate field-effect transistor and a method of manufacturing the same.

2. Description of the Related Art

As an active device that constitutes a part of a semiconductor integrated circuit device, there is known an insulated-gate field-effect transistor (hereinafter referred to as “transistor”) that is typified by a MOS transistor or a MIS transistor. The transistor includes a gate electrode that is formed on a semiconductor substrate, and source/drain regions that are formed in the semiconductor substrate on both sides of the gate electrode. In the transistor, the source region and drain region can be connected and disconnected in accordance with a potential that is applied to the gate electrode. Taking advantage of this characteristic, the transistor is widely used as a switching device in the semiconductor integrated circuit device.

In the conventional transistor, however, both end portions of the gate electrode are led out in the gate width direction from the device region to a location on device isolation regions (the led-out part is referred to as “fringe” in the specification). A contact line for applying a potential to the gate electrode is put in contact with the fringe (see, e.g. Jpn. Pat. Appln. KOKAI Publication No. 2000-58800).

The fringe is also provided on a neighboring transistor in the gate width direction. Thus, if a processing limit is “F”, a distance of about “3F+α” needs to be provided between neighboring transistors. That is, this distance is a sum of two fringes “2F”, a distance “F” for device isolation and an alignment tolerance “α”. The provision of this distance is disadvantageous for microfabrication.

Besides, a potential that is applied to the fringe causes an electric field around the fringe. The electric field adversely affects the gate electrode and source/drain region of the neighboring transistor. Consequently, the potentials of the gate electrode and source/drain region of the neighboring transistor may become unstable. Thus, if a sufficient distance is not provided for device isolation, the reliability of the integrated circuit would deteriorate. This problem is particularly serious in a transistor that handles a high voltage, typically a write voltage, in a nonvolatile semiconductor memory.

### BRIEF SUMMARY OF THE INVENTION

According to an aspect of the present invention, there is provided a semiconductor integrated circuit device comprising an insulated-gate field-effect transistor, the insulated-gate field-effect transistor comprising: a device isolation insulating film that is provided to extend from an inside of a semiconductor substrate and to project from an upper surface of the semiconductor substrate, and defines a device region on the semiconductor substrate; a gate insulation film that is provided on the device region; a gate electrode that is provided on the gate insulation film; source/drain regions that are provided in the semiconductor substrate on both sides of the gate electrode; an insulation layer that is provided on the gate electrode; and a contact line that penetrates the insulation layer and is put in contact with the gate electrode, wherein two opposed side walls of side walls of the gate electrode are put in contact with the device isolation insulating film, and a gate width of the gate electrode is defined by the device isolation insulating film.

According to another aspect of the present invention, there is provided a semiconductor integrated circuit device comprising an insulated-gate field-effect transistor, the insulated-gate field-effect transistor comprising: a device isolation insulating film that is provided to extend from an inside of a semiconductor substrate and to project from an upper surface of the semiconductor substrate, and defines a device region on the semiconductor substrate; a gate insulation film that is provided on the device region; a gate electrode that is provided on the gate insulation film; source/drain regions that are provided in the semiconductor substrate on both sides of the gate electrode; an insulation layer that is provided on the gate electrode; and a contact line that penetrates the insulation layer and is buried in the gate electrode, wherein two opposed side walls of side walls of the gate electrode are put in contact with the device isolation insulating film, and a gate width of the gate electrode is defined by the device isolation insulating film.

According to still another aspect of the present invention, there is provided a method of manufacturing a semiconductor integrated circuit device, comprising: forming a gate insulation film on a semiconductor substrate; forming a gate electrode on the gate insulation film; forming an insulation layer on the gate electrode; forming a first trench that defines a device region on the semiconductor substrate, the first trench penetrating the insulation layer, the gate electrode and the gate insulation film and reaching a point within the semiconductor substrate; burying an insulator in the first trench, thereby forming a device isolation insulating film; and forming a contact line that penetrates the device isolation insulating film and contacts the gate electrode.

### BRIEF DESCRIPTION OF THE SEVERAL VIEWS OF THE DRAWING

FIG. 1 is a circuit diagram that shows a semiconductor device according to a first embodiment of the present invention;

FIG. 2 is a plan view that shows a part of a memory cell array of the semiconductor device according to the first embodiment;

FIG. 3 is a cross-sectional view taken along line 3-3 in FIG. 2;

FIG. 4 is a circuit diagram for describing a capacitance ratio in the semiconductor device according to the first embodiment;

FIG. 5 is a plan view that shows a part of a row decoder of the semiconductor device according to the first embodiment;

FIG. 6 is a cross-sectional view taken along line 6-6 in FIG. 5;

FIG. 7 is a cross-sectional view taken along line 7-7 in FIG. 5;

FIG. 8 is a cross-sectional view that shows a part of a cell row, for describing a write operation of the semiconductor device according to the first embodiment;

FIG. 9 is a cross-sectional view that shows a part of a cell row, for describing a read operation of the semiconductor device according to the first embodiment;

FIG. 10A to FIG. 10D illustrate a fabrication step of the semiconductor device according to the first embodiment, FIG. 10A being a cross-sectional view taken along line 3-3 in FIG. 1, FIG. 10B being a cross-sectional view taken along line B-B in FIG. 1, FIG. 10C being a cross-sectional view taken along line C-C in FIG. 1, and FIG. 10D being a cross-sectional view taken along line D-D in FIG. 1;

FIG. 10E and FIG. 10F illustrate a fabrication step of the semiconductor device according to the first embodiment, FIG. 10E being a cross-sectional view taken along line 6-6 in FIG. 5, and FIG. 10F being a cross-sectional view taken along line 7-7 in FIG. 5;

FIG. 11A to FIG. 11F are cross-sectional views illustrating a fabrication step subsequent to the fabrication step shown in FIGS. 10A to 10F;

FIG. 12A to FIG. 12F are cross-sectional views illustrating a fabrication step subsequent to the fabrication step shown in FIGS. 11A to 11F;

FIG. 13A to FIG. 13F are cross-sectional views illustrating a fabrication step subsequent to the fabrication step shown in FIGS. 12A to 12F;

FIG. 14A to FIG. 14F are cross-sectional views illustrating a fabrication step subsequent to the fabrication step shown in FIGS. 13A to 13F;

FIG. 15A to FIG. 15F are cross-sectional views illustrating a fabrication step subsequent to the fabrication step shown in FIGS. 14A to 14F;

FIG. 16A to FIG. 16F are cross-sectional views illustrating a fabrication step subsequent to the fabrication step shown in FIGS. 15A to 15F;

FIG. 17A to FIG. 17F are cross-sectional views illustrating a fabrication step subsequent to the fabrication step shown in FIGS. 16A to 16F;

FIG. 18A to FIG. 18F are cross-sectional views illustrating a fabrication step subsequent to the fabrication step shown in FIGS. 17A to 17F;

FIG. 19A to FIG. 19F are cross-sectional views illustrating a fabrication step subsequent to the fabrication step shown in FIGS. 18A to 18F;

FIG. 20A to FIG. 20F are cross-sectional views illustrating a fabrication step subsequent to the fabrication step shown in FIGS. 19A to 19F;

FIG. 21 is a plan view that shows a semiconductor device according to a second embodiment of the invention; and

FIG. 22 is a cross-sectional view taken along line 22-22 in FIG. 21.

### DETAILED DESCRIPTION OF THE INVENTION

Embodiments of the present invention will now be described with reference to the accompanying drawings. In the description below, common parts are denoted by like reference numerals throughout the drawings.

### First Embodiment

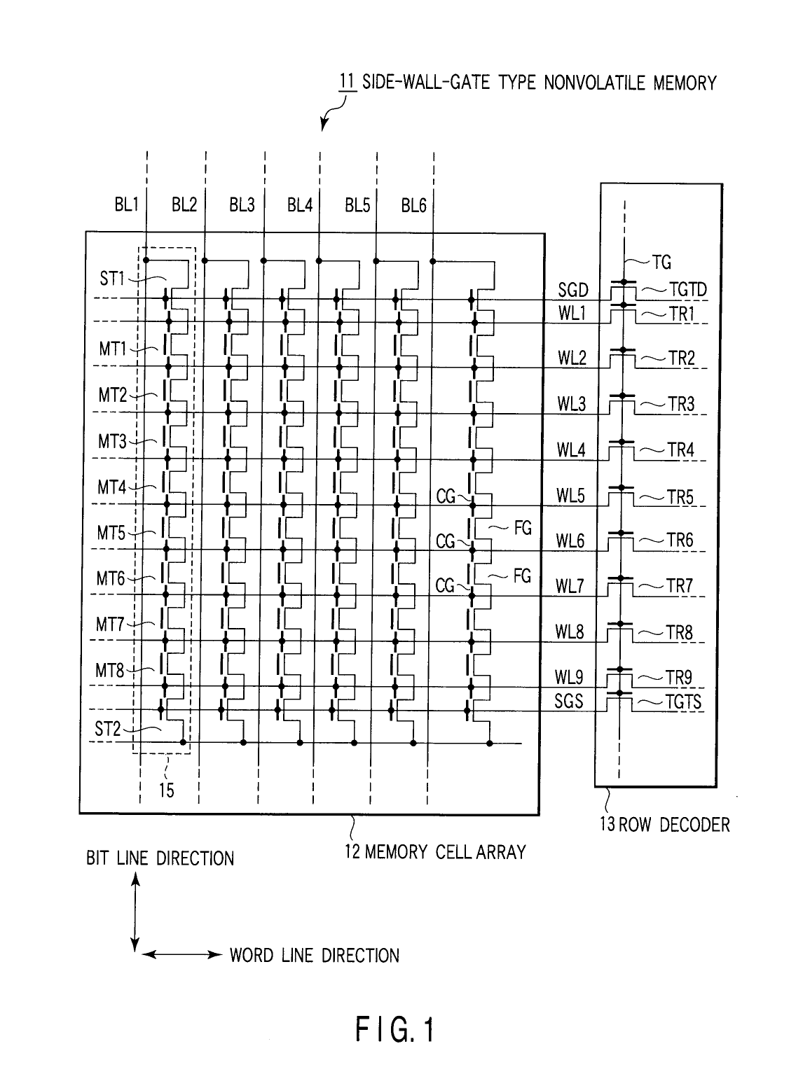

A semiconductor integrated circuit device including insulated-gate field-effect transistors according to a first embodiment of the invention and a method of manufacturing the semiconductor integrated circuit device will now be described with reference to FIG. 1 through FIG. 19F, taking a nonvolatile semiconductor memory by way of example. In the nonvolatile semiconductor memory of this embodiment, control gates for driving a floating gate are provided on both sides of the floating gate. In this specification, this memory is referred to as “side-wall-gate type”.

The side-wall-gate type nonvolatile semiconductor memory is disclosed in Japanese Patent Application No. 2003-207566 that was filed by the applicant of the present application.

FIG. 1 is a circuit diagram that shows a memory cell array of a side-wall-gate type nonvolatile semiconductor memory, and a part of its peripheral circuit.

As shown in FIG. 1, the side-wall-gate type nonvolatile semiconductor memory 11 comprises a memory cell array 11 And a peripheral circuit 11 For simple depiction, FIG. 1 shows only a part of the peripheral circuit 11 For instance, only a transfer gate transistor part of a row decoder.

The peripheral circuit 11 For instance, the row decoder, selects two of nine word lines (control gates) WL1 to WL9, and select gate lines SGD and SGS in accordance with an address signal (not shown). Signals that select these elements are supplied to the word lines WL1 to WL9 and select gate lines SGD and SGS via transistors TR1 to TR9 and transfer gate transistors TGTD and TGTS that are provided in the row decoder 13. The transistors TR1 to TR9, TGTD and TGTS are formed as high-voltage transistors in order to pass, e.g. a write potential at a write operation time.

The memory cell array 12 includes 8 memory cell transistors MT and select transistors ST1 and ST2, which are commonly connected to any one of bit lines BL1 to BL6. The number of memory cell transistors MT is not limited to 8, and it may be, e.g. 16 or 32. Both select transistors ST1 and ST2 are not necessarily required.

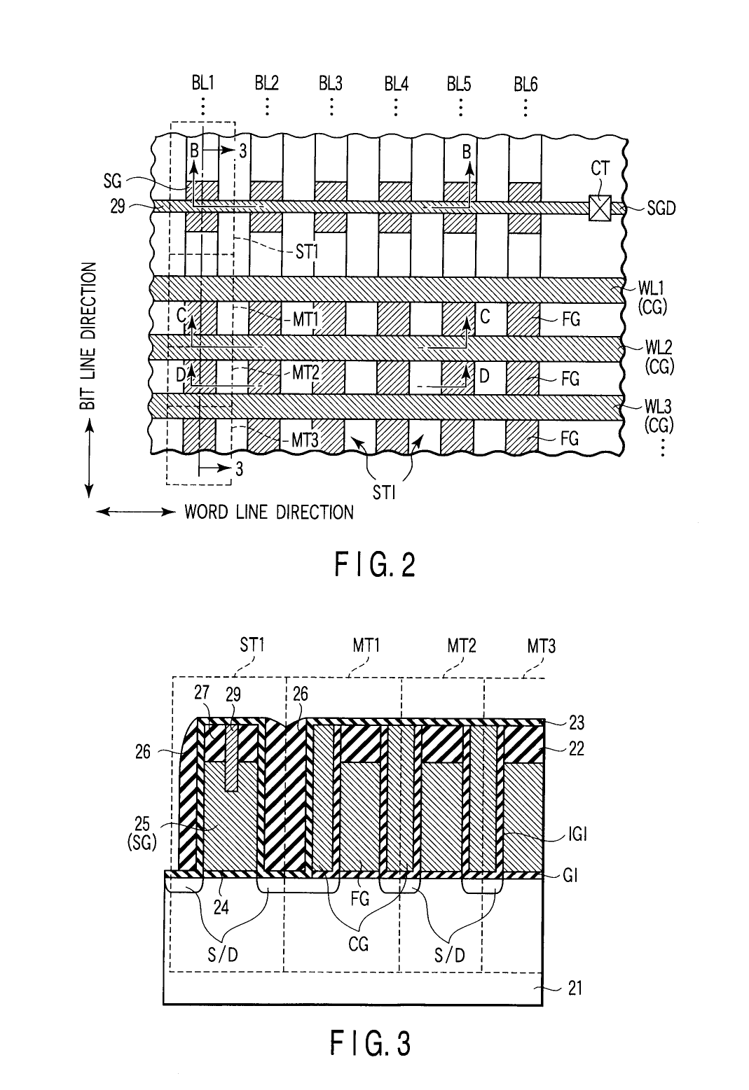

Next, the memory cell transistor MT and select transistor ST are described with reference to FIG. 2 and FIG. 3.

FIG. 2 is a plan view that shows a part of the memory cell array 12 shown in FIG. 1. FIG. 3 is a cross-sectional view taken along line 3-3 in FIG. 2.

As shown in FIGS. 2 and 3, each of memory cell transistors MT1 to MT3 includes a floating gate FG that is provided via a gate insulation film GI on a substrate 21; control gates CG that are provided on both sides of the floating gate FG via inter-gate insulation films IGI; and a source and a drain (S/D) that are formed of diffusion layers in the substrate 21 so as to sandwich the floating gate FG.

The control gates CG contact both side walls of the floating gate and the diffusion layers via the inter-gate insulation films IGI. In the conventional memory cell, one floating gate FG is driven by one control gate CG. By contrast, in the side-wall-gate type memory cell, one floating gate FG is driven by two control gates CG that are located on both sides of the floating gate FG.

The select transistor ST1 comprises a gate electrode 25 that is provided via a gate insulation film 24 on the substrate 21; an insulation layer 27 provided on the gate electrode 25; a source and a drain (S/D) that are formed of diffusion layers in the substrate so as to sandwich the gate electrode 25; a barrier film 23 that is provided over the source/drain, gate electrode 25 and insulation layer 27; a wiring layer 29 that penetrates the insulation layer 27 and is provided in the gate electrode 25; and a spacer 26 that is provided on side walls of the gate electrode 25. The wiring layer 29 is a select gate line SGD.

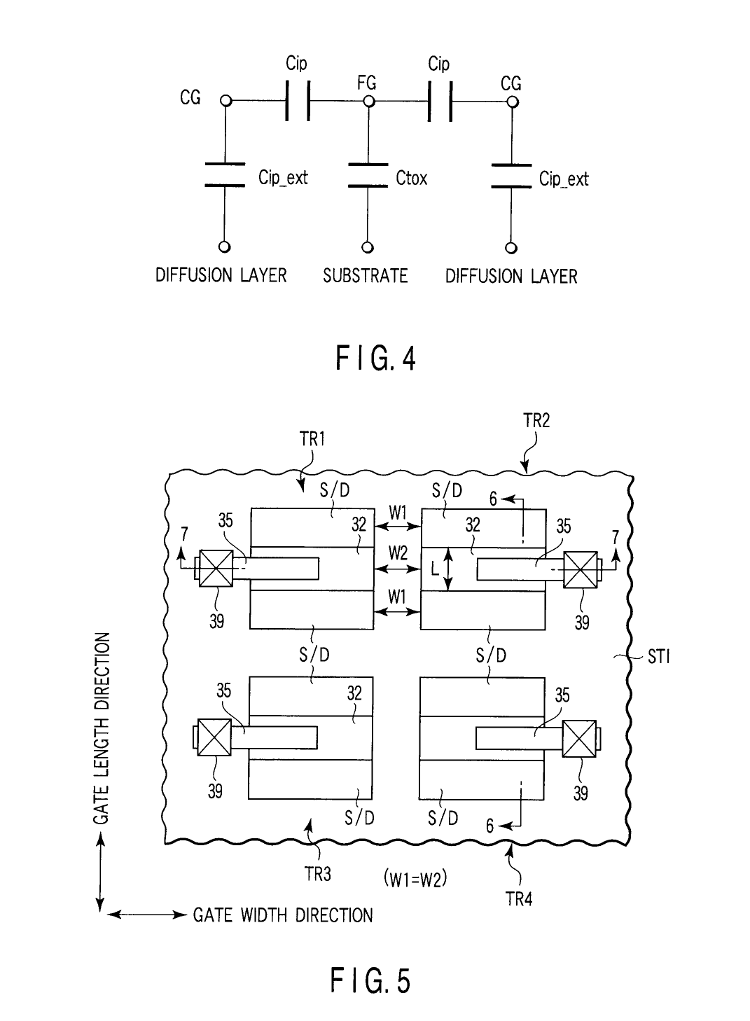

FIG. 4 is an equivalent circuit of the side-wall-gate type memory cell. Symbol Cip denotes a capacitance between the control gate CG and floating gate FG, Cip_ext denotes a capacitance between the control gate CG and the substrate, and Ctox designates a capacitance between the floating gate FG and the substrate. In this equivalent circuit, if two control gates CG that adjoin one floating gate FG have an equal potential (Vcg), a capacitance ratio that determines the potential Vfg of the floating gate is approximately given by

$$\begin{matrix}Cr = Cip / ( Cip + Ctox ) \\ = ( 2 \cdot ɛ ip \cdot W \cdot Tfg / Tip ) / ( ( 2 \cdot ɛ ip \cdot W \cdot Tfg / Tip ) + \\ ɛ tox \cdot W \cdot L / Ttox )\end{matrix}$$

where ε ip: the dielectric constant of the inter-gate insulation film, E tox: the dielectric constant of the tunnel insulation film, W: the width of the gate of the memory cell transistor, L: the gate length of the memory cell transistor, Tfg: the thickness of the FG film, Ttox: the thickness of the tunnel insulation film, and Tip: the thickness of the inter-gate insulation film.

It is understood, from the above equation, that in the side-wall-type memory cell, the Cr can be increased by increasing the film thickness Tfg of the floating gate, even if the gate width or gate length of the transistor that is to be a minimum processing dimension is not varied. This means that the capacitance ratio can be improved even if the cell structure is made finer.

In addition, as shown in the Figures, the space between the two floating gates FG is almost completely filled with the control gate CG. This structure can substantially shut off two parasitic capacitances, which have posed a problem in the conventional memory cell, that is, a coupling capacitance between the neighboring floating gates FG in the bit line BL direction, and a fringe capacitance between the substrate, where the source/drain of the memory cell transistor is formed, and the floating gate FG.

It is thus possible to secure a capacitance ratio by increasing the film thickness of the floating gate FG, without taking an increase in parasitic capacitance into account. As a result, the capacitance ratio can be increased even if the gate length or gate width of the memory cell transistor is decreased. Moreover, since the capacitance ratio can be increased, the write voltage can be decreased.

Next, referring to FIGS. 5 to 7, the transistors provided in the peripheral circuit 13 are described. For instance, high-voltage transistors TR that are provided in the row decoder in the peripheral circuit 13 are described.

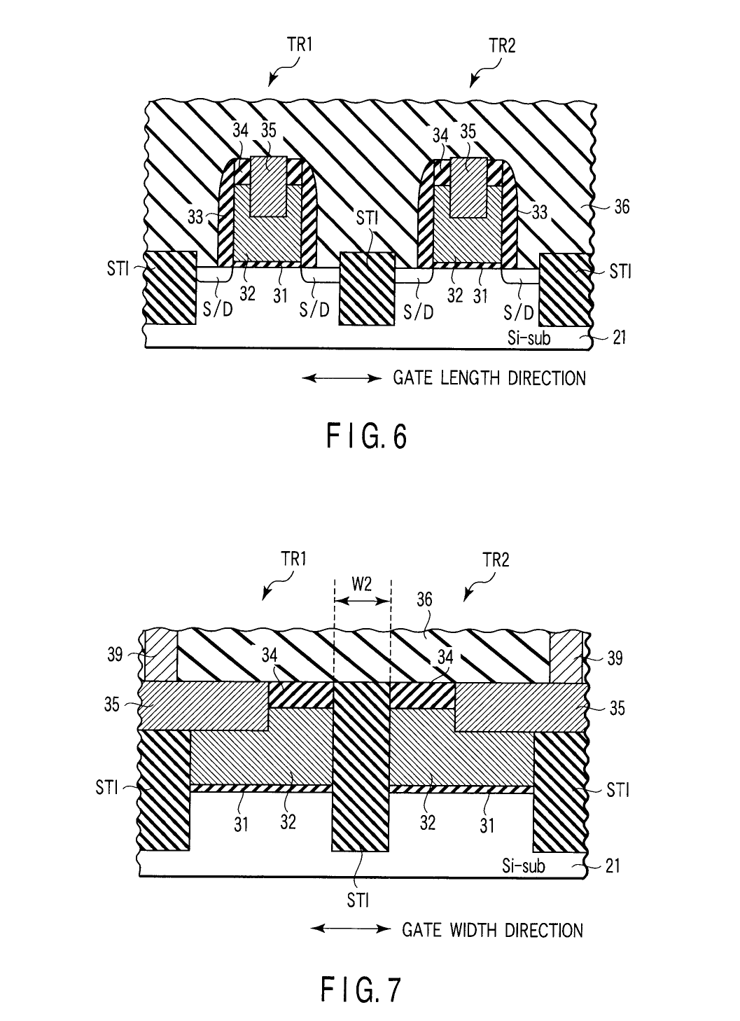

FIG. 5 is a plan view that shows a part of the peripheral circuit 13 in FIG. 1. FIG. 6 is a cross-sectional view taken along line 6-6 in FIG. 5. FIG. 7 is a cross-sectional view taken along line 7-7 in FIG. 5. By way of example, a transistor TR2 is representatively described.

As is shown in FIGS. 5 to 7, the transistor TR2 comprises a gate insulation film 31 provided in a device region on a major surface of the substrate 21, which is isolated by device isolation insulating films STI; a gate electrode 32 that is provided on the gate insulation film 31; an insulation film 34 that is provided on the gate electrode 32; a contact line 35 that penetrates the insulation film 34 and is provided in the gate electrode 32 and device isolation insulating film STI; spacers 33 that are provided on side walls of the gate electrode 32; and a gate contact plug 39 that is provided on the contact line 35 over the device isolation film STI. An insulating layer 36 is provided so as to cover the transistor TR2.

The contact line 35 penetrates the insulation layer 34 and is provided in the gate electrode and the device isolation film so as to extend in the gate width direction from a central part of the gate electrode 32 to the device isolation insulating film STI. The surface of the contact line 35 is continuous with the surface of the insulation film 34.

The distance W 2 between the gate electrodes 32 of the transistors TR1 and TR2, TR3 and TR4, which are adjacent to each other in the gate width direction, is set to be equal to the distance W1 between the sources/drains (S/D) of the transistors TR1 and TR2, TR3 and TR4, which are adjacent to each other in the gate width direction (FIG. 5 and FIG. 7). In other words, the side walls of the source/drain (S/D) and gate electrode in the gate length direction are made continuous.

The gate electrode 32 is provided to be surrounded by the device isolation insulating films STI and the insulation film 34. Thus, the gate electrode 32 has no fringe that projects onto the device isolation insulating film STI.

In this example, the gate contact plug 39 is provided on the contact line 35. Thus, even if the dimension of the gate contact is equal to or greater than the gate length L, short-circuit to the source/drain contact can be prevented.

Furthermore, the contact line 35 of the transistor TR and the wiring layer 29 (select gate line SGD) of the select transistor ST are formed of the same material such as polycrystalline silicon.

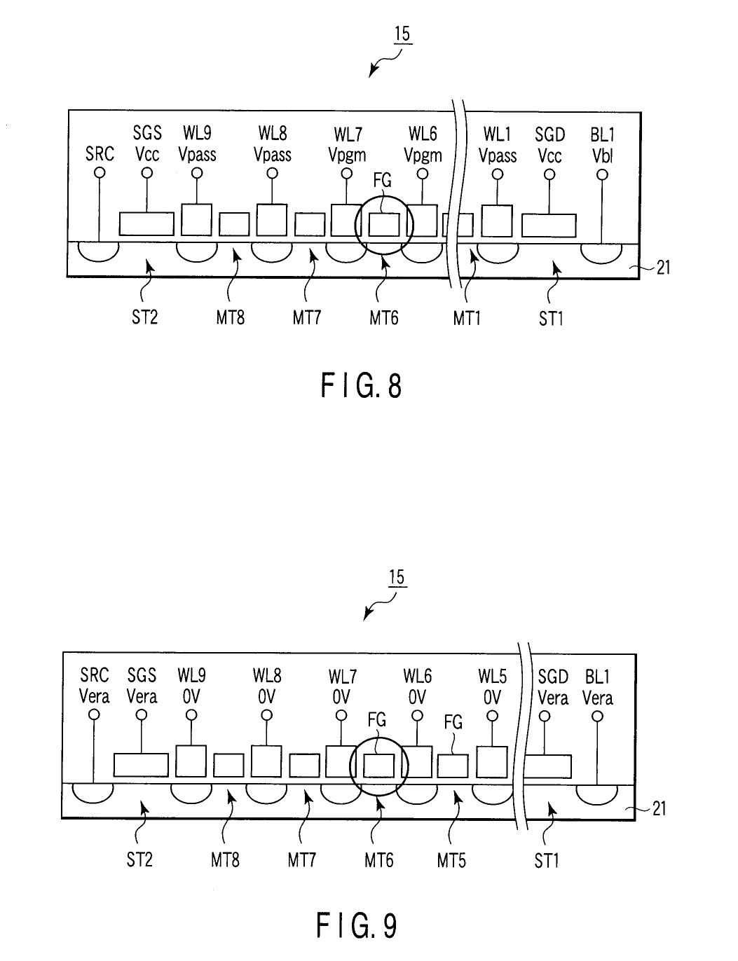

Next, an example of the write/read operation of the semiconductor device according to this embodiment is described. At first, an operation for writing data in the memory cell transistor MT is described. Referring to FIG. 8 and FIG. 9, an operation for writing data in the memory cell transistor MT6 is described by way of example. FIG. 8 is a cross-sectional view for explaining the operation for writing data in the memory cell transistor MT6.

To start with, a potential Vb1 is applied to the bit line BL1 shown in FIG. 1, a potential Vcc is applied to the select gate lines SGS and SGD, and a potential Vcc is applied to the bit lines BL2 to BL6. Thereby, a cell array 15 that is connected to the bit line BL1 is selected.

Then, a potential VpgmH (Vpgm+Vth) for transferring a write voltage Vpgm to the word lines (selected word lines) WL6 and WL7 is applied to the transfer gate line TG. The potential VpgmH turns on the transistors TR1 to TR9 and transfer gate transistors TGTD and TGTS of the row decoder 13.

For example, the same write voltage Vpgm is transferred from the transistors TR6 and TR7 to the two word lines WL (control gates CG) that adjoin the floating gate FG to be selected, and the substrate 21 is set at, e.g. 0V. An intermediate potential Vpass is transferred from the transistors TR1 to TR5, TR8 and TR9 to the non-selected word lines WL1 to WL5, WL8 and WL9. In this state, a charge is injected from the substrate 21 into the floating gate FG of the selected memory cell transistor MT6, and data is written in the memory cell transistor MT6.

Next, the erase operation is similarly described. FIG. 9 is a cross-sectional view for explaining the erase operation.

As is shown in FIG. 9, a potential is applied to the transfer gate line TG to turn on the transistors TR1 to TR9 and transfer gate transistors TGTD and TGTS. A ground potential of 0V is transferred to the word lines WL1 to WL9, and an erase potential Vera is transferred to the select gate lines SGS and SGD. Further, the potential of the substrate 21, on which the memory transistors MT1 to MT8 are provided, is raised to the erase potential Vera. At the same time, the potential of the contact CT, bit line BL1 and common source line SRC is raised to the same erase potential Vera as the substrate 21, in order to prevent destruction. In addition, a sufficiently low potential, e.g. about 0V, is applied to the word lines WL1 to WL9 (control gate CG) in the cell row 15 to be erased. Then, a charge is drawn from the floating gate FG of the memory cell transistor MT6 to the substrate 21 with the raised potential. Thus, data is erased.

As has been described above, the write/erase operation for the side-wall-gate type memory cell transistor is executed.

The semiconductor device of the present embodiment, as described above, includes the contact line 35, whose one end portion in the gate width direction is provided in the gate electrode 32 and the other end portion in the gate width direction is extended and provided on the device isolation insulating film STI. In addition, the surface of the contact line 35 is continuous with the surface of the insulation layer 34. Further, the gate electrode 32 is provided to be surrounded by the device isolation insulating film STI and the insulation layer 34. Thus, the gate electrode 32 has no fringe that projects onto the device isolation film STI, and the gate width of the gate electrode 32 is defined by the device isolation insulating film STI (FIG. 7).

The gate electrode 32 has no fringe. Hence, if a processing limit is “F”, a distance of about “3F+α need not be provided between neighboring transistors TR1 and TR2 in the gate width direction. This distance is a sum of two fringes “2 F”, a distance “F” for device isolation and an alignment tolerance “α”. Since the gate electrode 32 has no fringe, the distance between the neighboring transistors TR1 and TR2 in the gate width direction can approximately be set at W2, which is less than the sum distance of about “3F+α” (FIG. 7) . As a result, the distance in the gate width direction can be reduced, and this is advantageous for microfabrication. In particular, the distance between the neighboring transistors TR1 and TR2 in the gate width direction can approximately be set at the processing limit F.

Even in the case where the high potential VpgmH for transferring the write voltage Vpgm is applied to the gate electrode 32 via the gate contact plug 39, it is possible to prevent electric lines of force (electric field) from extending to the gate electrodes and source/drain regions of the neighboring transistors (e.g. TR1 and TR2) and making unstable the potential of the gate electrodes and the potential of the source/drain regions of the neighboring transistors. In other words, by defining the gate width of the gate electrode 32 by the device isolation insulating films STIs, the device isolation performance is enhanced and the reliability of the integrated circuit would not be deteriorated even if further microfabrication is implemented. This is advantageous in increasing the integration density of the integrated circuit, in particular, the integration density of the integrated circuit that handles a high voltage, such as a nonvolatile semiconductor memory.

Furthermore, the gate contact plug 39 is provided on the contact line 35 that extends in the gate width direction. Thus, even in the case where the diametrical dimension of the gate contact plug 39 is equal to or greater than the gate length L, short-circuit to the source/drain can be prevented. It is possible, therefore, to easily control the gate electrode 39 and the source/drain independently.

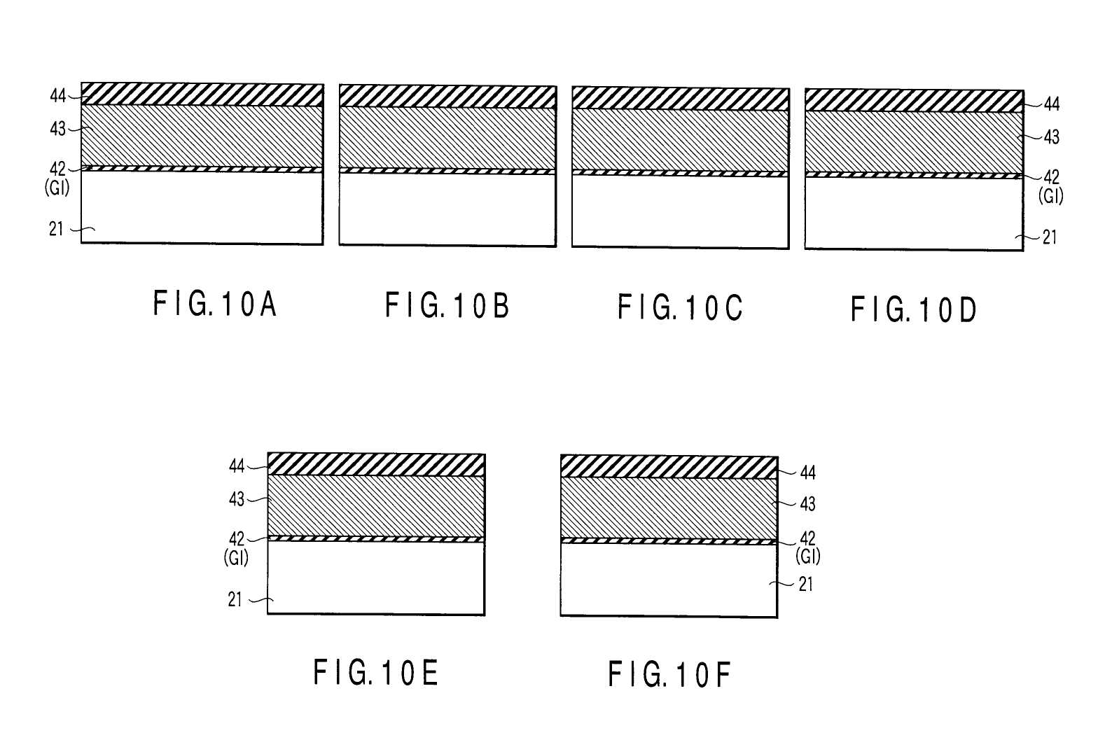

Next, a method of manufacturing a semiconductor device according to this embodiment is described with reference to FIGS. 10A-10F through FIGS. 20A-20F.

FIG. 10A through FIG. 20A are views for describing the method of manufacturing the semiconductor device, and are cross-sectional views taken along line 3-3 in FIG. 2. FIG. 10B to FIG. 20B are cross-sectional views taken along line B-B in FIG. 2. FIG. 10C to FIG. 20C are cross-sectional views taken along line C-C in FIG. 2. FIG. 10D to FIG. 20D are cross-sectional views taken along line D-D in FIG. 2. FIG. 10D to FIG. 20D are cross-sectional views taken along line D-D in FIG. 2. FIG. 10E to FIG. 20E are cross-sectional views taken along line 6-6 in FIG. 5. FIG. 10F to FIG. 31F are cross-sectional views taken along line 7-7 in FIG. 5.

To start with, as shown in FIGS. 10A to 10D and FIGS. 10E and 10F, in a memory cell array section and a peripheral circuit section, a surface of a semiconductor substrate 21 that contains, e.g. silicon is subjected to thermal oxidation, and a gate insulation film 42 (GI) that includes, e.g. a silicon oxide film is formed. On the gate insulation film 42, a polycrystalline silicon layer 43, of which the floating gate FG is to be formed, is provided. A mask layer 44 is formed on the polycrystalline silicon layer 43. An example of the material of the mask layer 44 is a burying material that forms a device isolation insulating film in a subsequently performed CMP (Chemical Mechanical Polishing) step, or a material that provides a large selection ratio relative to the material of the control gate CG. Silicon nitride (SiN) film is an example of the mask layer 44.

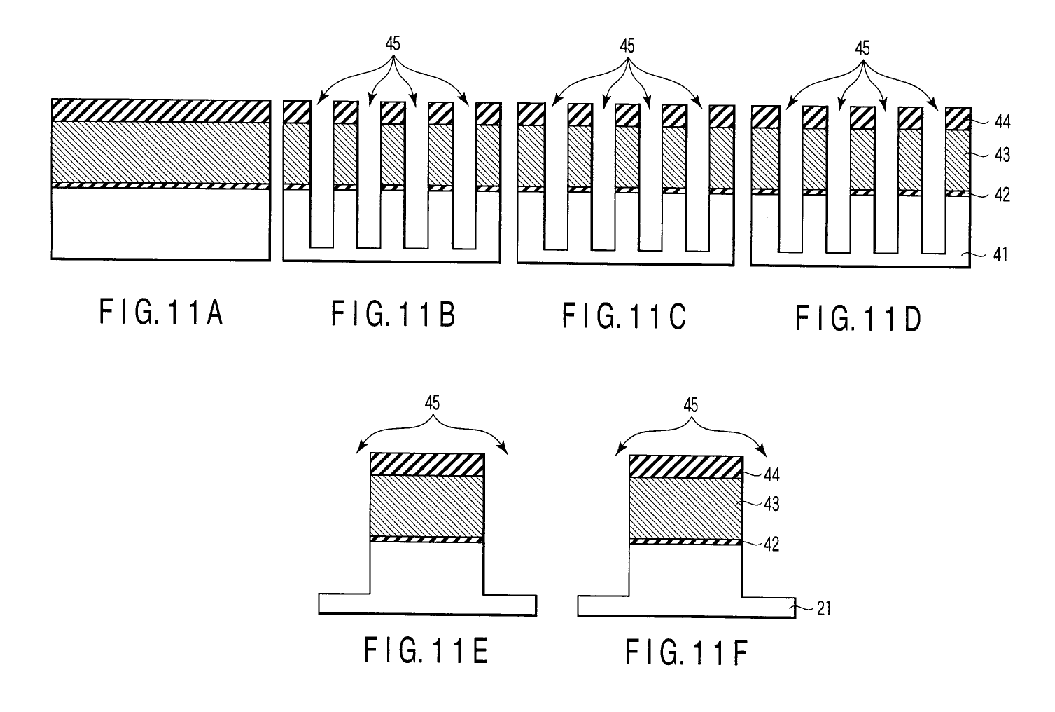

As shown in FIGS. 11A to 11F, using a mask pattern (not shown) as a mask, the mask layer 44, polycrystalline silicon layer 43, gate insulation film 42 and semiconductor substrate 21 are anisotropically etched by, e.g. RIE, thereby forming a plurality of trenches 45 for device isolation, which reach the semiconductor substrate 21 through the mask layer 44, polycrystalline silicon layer 43 and gate insulation film 42.

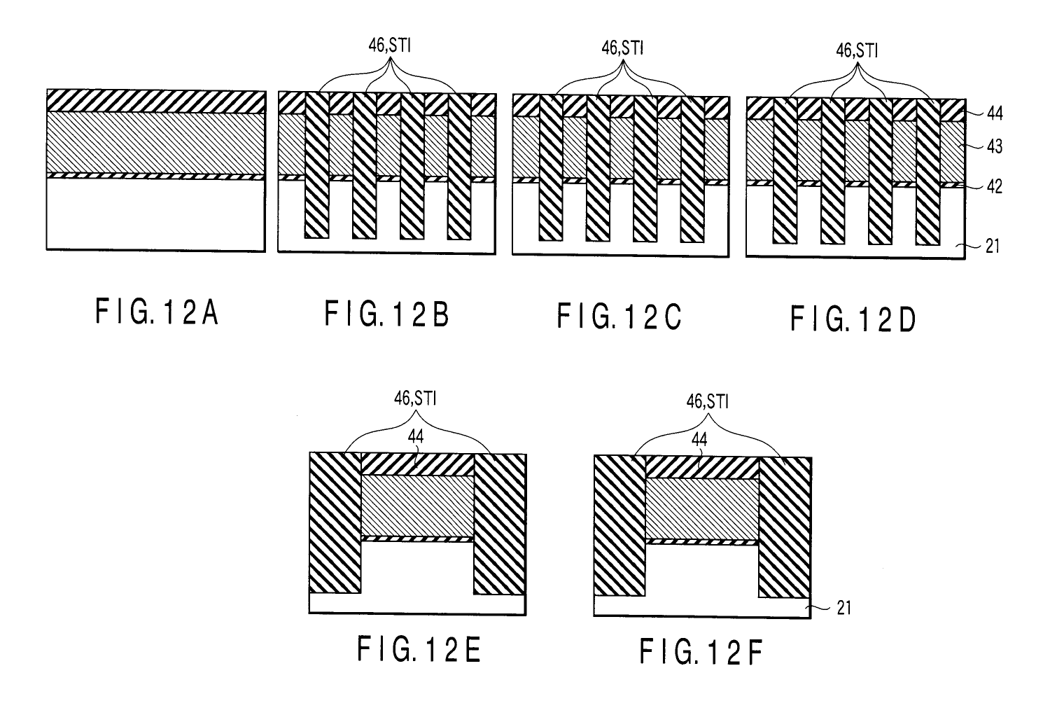

Subsequently, as shown in FIGS. 12A to 12 F, an insulator 46 for device isolation is buried in the trenches 45. An example of the insulator is silicon oxide (SiO₂). Using the mask layer 44 as a stopper for polishing, the insulating film 46 is planarized by, e.g. CMP, and device isolation insulating films STIs are formed.

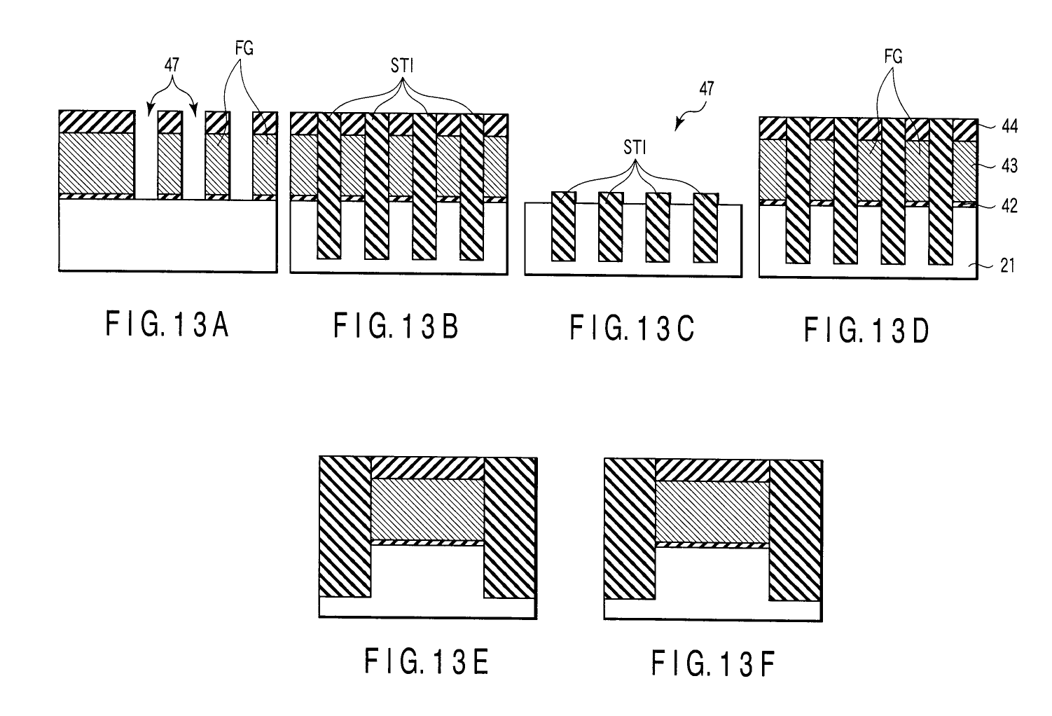

In a step illustrated in FIGS. 13A to 13 F, the mask layer 44, polycrystalline silicon layer 43, gate insulation film 42 and device isolation insulating film STIs, which will subsequently adjoin control gates CG, are etched and selectively removed by, e.g. RIE down to the substrate 21 so as to correspond to formation regions of the control gates CG.

In this way, trenches 47 for forming control gates CG (word lines WL) are formed, and floating gates FG that are defined by the trenches 47 are formed. Specifically, the trench 47 extend perpendicular to the device isolation films STIs. As shown in FIG. 13C, the polycrystalline silicon layer 43 on the gate insulation film 42 is removed in the trench 47, and the device isolation films STIs are removed such a degree that they project from the gate insulation film 42.

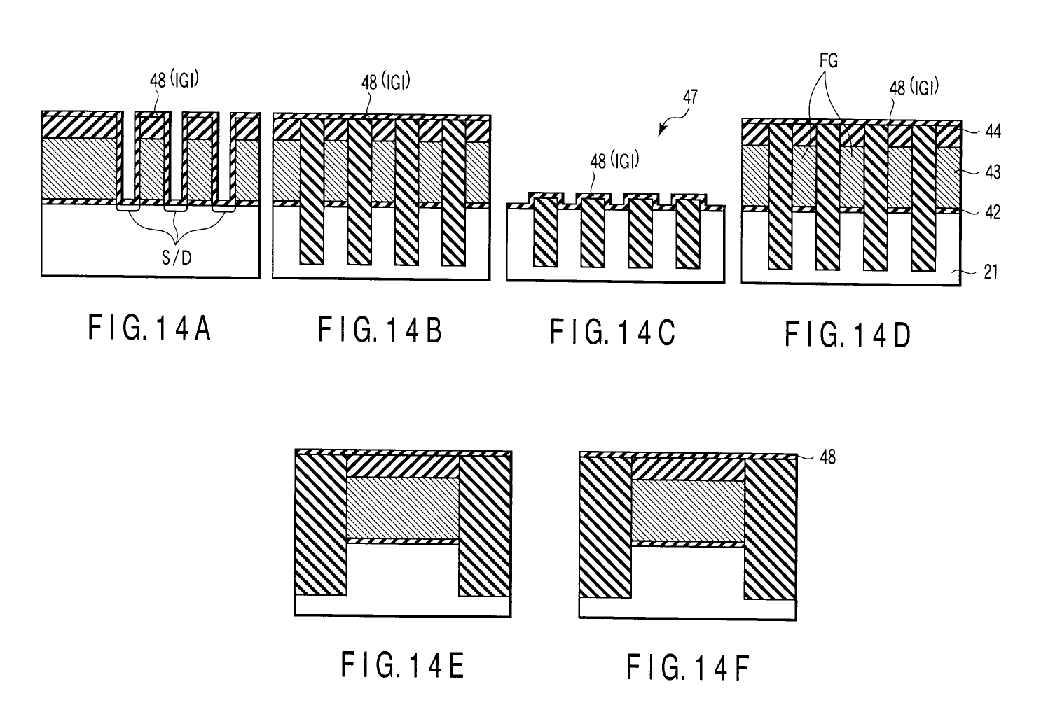

Then, as shown in FIGS. 14A to 14F, impurity ions are implanted in those parts of the semiconductor substrate 21, which are located between the floating gates FG. Thus, sources/drains S/D are formed. Following this, an inter-gate insulation film 48 (IGI) is formed on exposed surfaces of the mask layer 44, polycrystalline silicon layer 43, substrate 21 and device isolation films STIs. An example of the inter-gate insulation film 48 is an ONO film in which an oxide film, a nitride film and an oxide film are stacked.

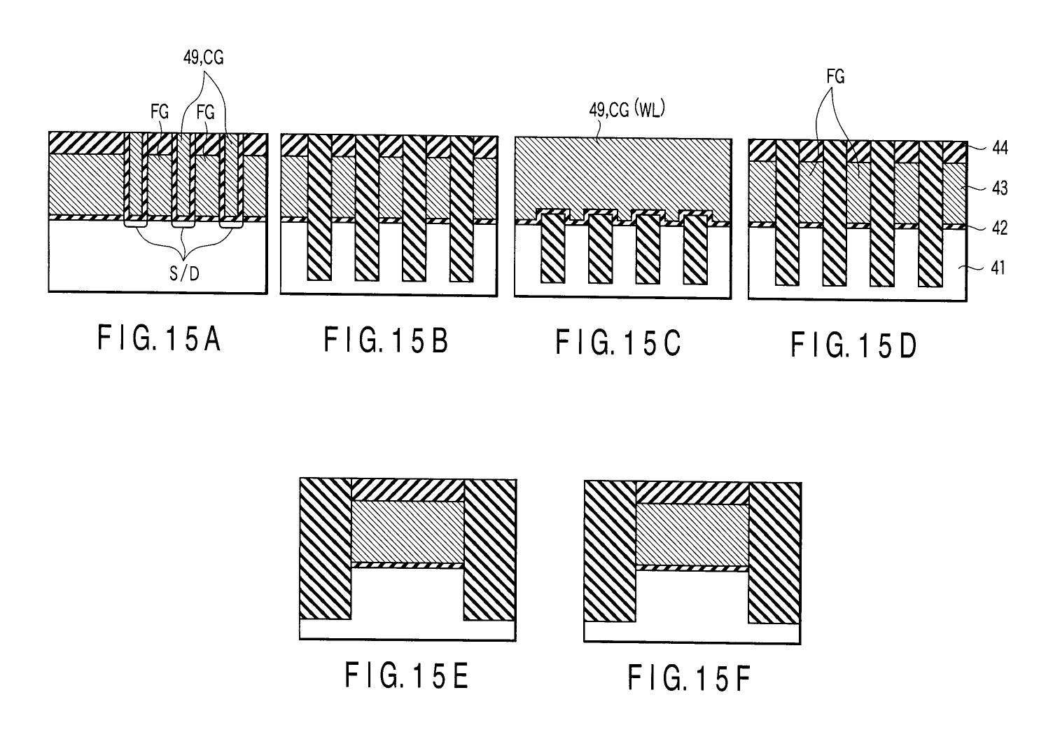

In a subsequent step illustrated in FIGS. 15A to 15F, a polycrystalline silicon layer 49, for instance, is formed on the inter-gate insulation film 48. Using the mask layer 44 as a stopper, the polycrystalline silicon layer 49 is planarized by, e.g. CMP or dry etching. Thus, control gates CG are formed on side walls of the floating gates FG, as shown in FIG. 15A. The neighboring control gates CG are connected on the device isolation films STIs, as shown in FIG. 15C, thereby forming word liens WL.

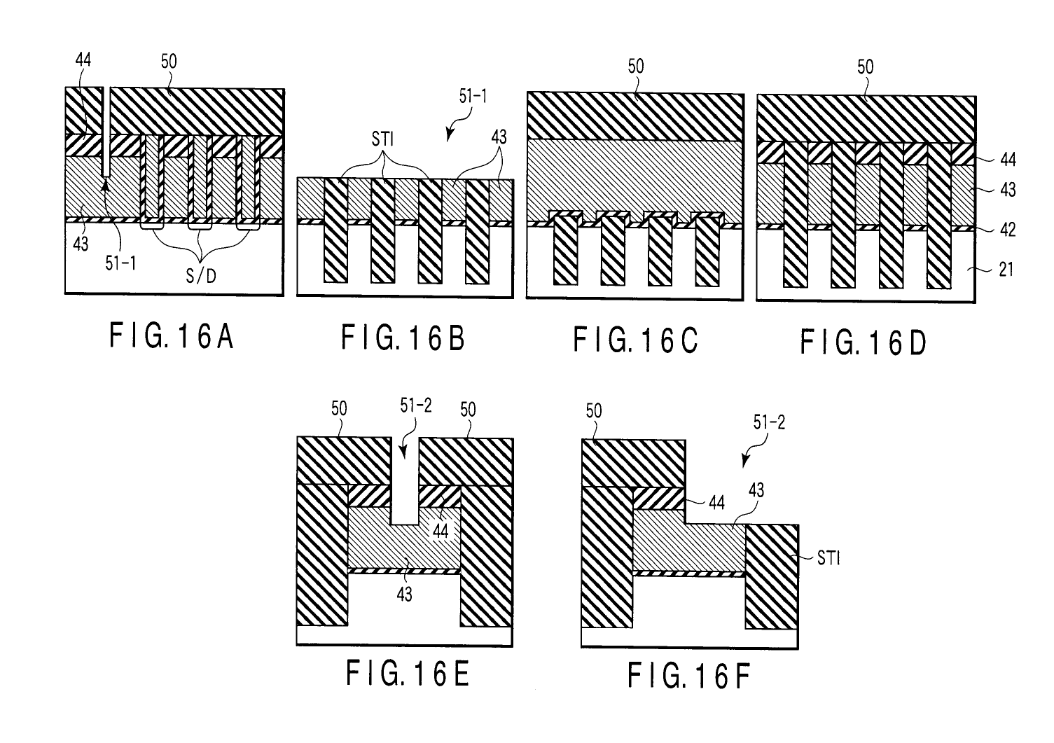

In a step illustrated in FIGS. 16A to 16F, a mask layer 50 is formed, except for a formation area of a select gate line that is to be disposed in a subsequent step in the direction of the word lines WL and interconnects a plurality of select gate electrodes SG, that is, a formation area of a wiring layer 29, and a formation area of a contact line 35 in the peripheral circuit section. Using the mask layer 50 as a mask, anisotropic etching such as RIE is performed to form trenches 51-1 and 51-2 that penetrate the mask layer 44 at the formation areas of the wiring layer 29 and contact line 35 and are formed in the polycrystalline silicon layer 43.

The width of the trench 51-1 shown in FIG. 16A may be made equal to the width of the trench 51-2 shown in FIG. 16E. In the case where both widths are made equal, a high resolution is attained for both trenches 51-1 and 51-2 in the lithography step of etching the mask layer 50, and this is advantageous for microfabrication.

In the case where the width of the trench 51-2 is made equal to the width of the trench 51-1, the contact line 35 that is to be formed later becomes too fine and an increase in resistance value is likely to occur. In this case, a plurality of trenches 51-2 each having the same width as the trench 51-1 may be formed on each gate electrode 32.

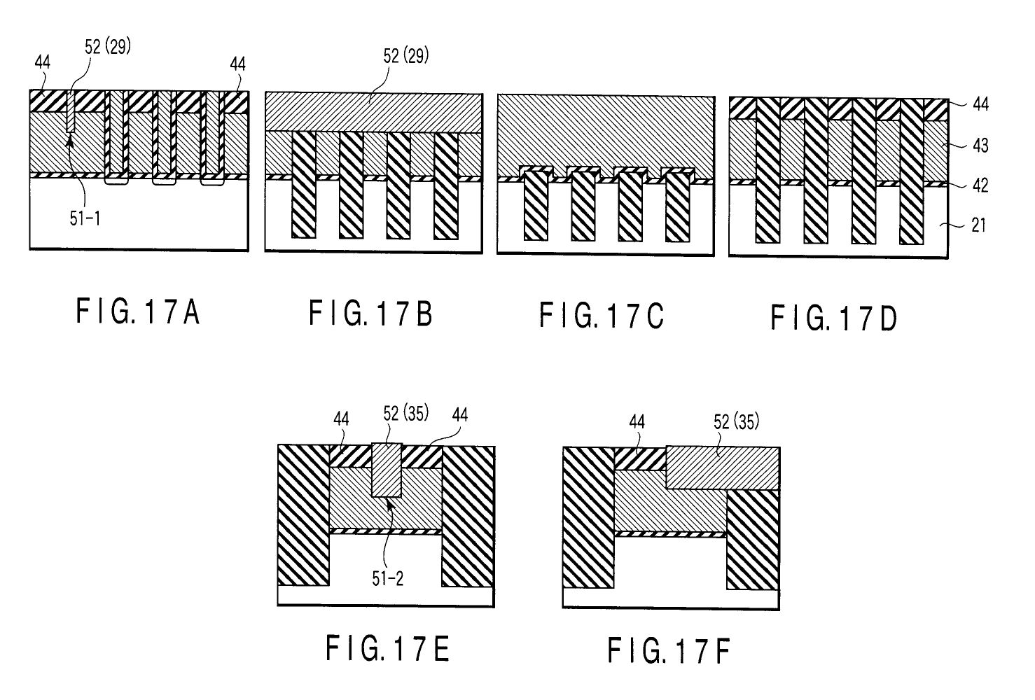

Thereafter, as shown in FIGS. 17A to 17F, the mask layer 50 is removed and a polycrystalline silicon layer 52, for instance, is buried in the trenches 51-1 and 51-2, thereby forming a wiring layer 29 in the trench 51-1 and a contact line 35 in the trench 51-2. The polycrystalline silicon layer 52 is planarized by, e.g. CMP. As a result, the upper surface of the wiring layer 29 and the upper surface of the contact line 35 are planarized on the same level as the upper surface of the mask layer 44.

The material of the wiring layer 29 and contact line 35 is not limited to polycrystalline silicon, and it may be any low-resistance material such as tungsten silicide.

In addition, a slight amount of native oxide film with electrical conductivity may be present between the polycrystalline silicon layer 43 and polycrystalline silicon layer 52.

The concentration of N-type or P-type impurities in the polycrystalline silicon layer 52 may be lower than that of N-type or P-type impurities in the polycrystalline silicon layer 43. The advantage in this case is that the rate of oxidation of the polycrystalline silicon layer 52 lowers and it is possible to prevent the polycrystalline silicon layer 52 from becoming a silicon oxide film due to accidental oxidation. The lower limit value of the concentration of impurities in the polycrystalline silicon layer 52 is such a value that the conductivity type of the polycrystalline silicon layer is not inverted or ohmic contact with the gate contact plug 39 is maintained in the step of introducing impurities in the source/drain region of the transistor TR that is formed in the peripheral circuit.

It is advantageous that the polycrystalline silicon layer 52 is buried down to a point above the lower surface of the polycrystalline silicon layer 43 and the polycrystalline silicon layer 43 is present between the gate insulation film 42 and the polycrystalline silicon layer 52, as in this example. The advantage is that the gate insulation film 42 is protected by the polycrystalline silicon layer 43 when the trenches 51-1 and 511 Are formed.

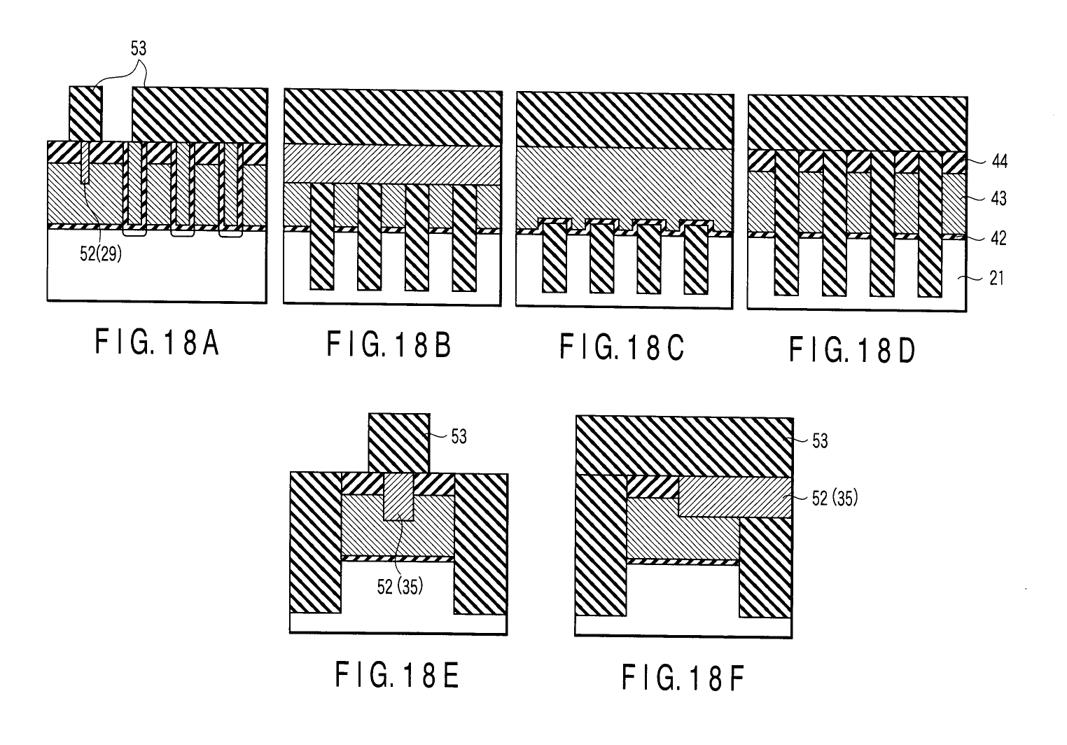

In the following step of FIGS. 18A to 18F, mask layers 53 having the width of the select gate SG and the width of the gate electrode are formed on the formation region of the select gate electrode SG and the formation region of the gate electrode of the transistor TR in the peripheral circuit section. As is shown in FIG. 18A and FIG. 18E, the mask layers 53 cover the wiring layer 29 and contact line 35.

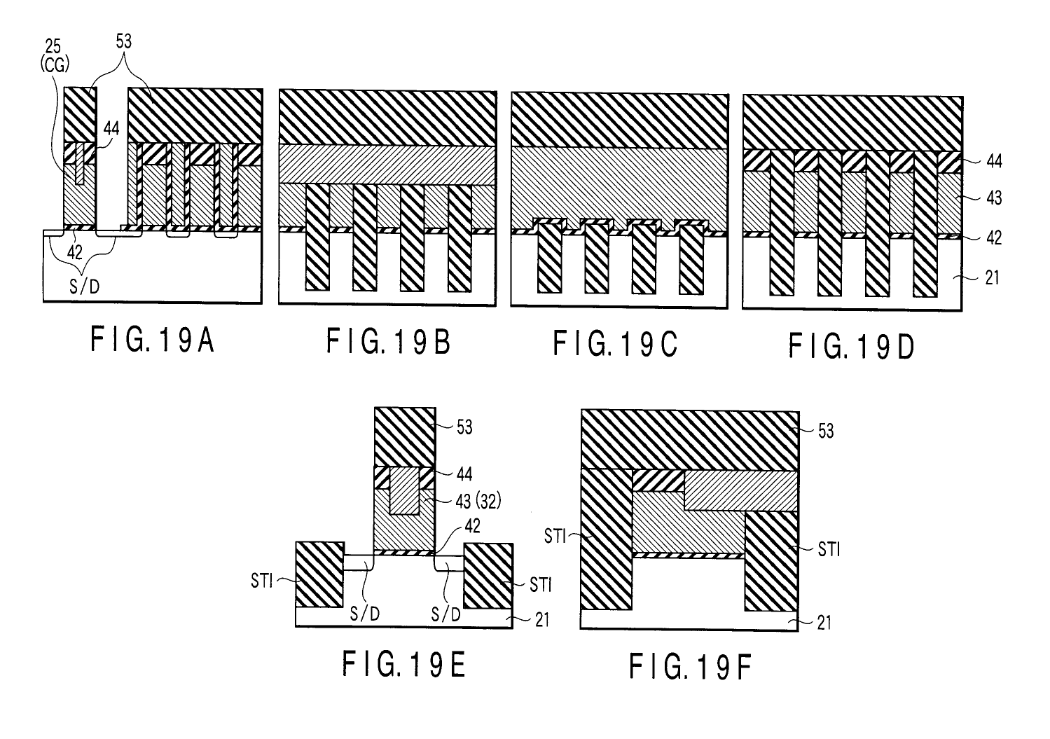

In a step illustrated in FIGS. 19A to 19F, using the mask layer 53 as a mask, anisotropic etching such as RIE is performed down to the surface of the substrate 21, thereby etching away parts of the mask layer 44, polycrystalline silicon layer 43, gate insulation film 42 and device isolation insulating film STI. Thus, a select gate electrode SG (25) is formed and a gate electrode 32 of the transistor is formed in the peripheral circuit section. After the removal of the mask layer 53, impurity ions are implanted in the semiconductor substrate 21 using the select gate electrode SG and gate electrode 32 as masks, thereby forming diffusion layers that serve as sources/drains (S/D).

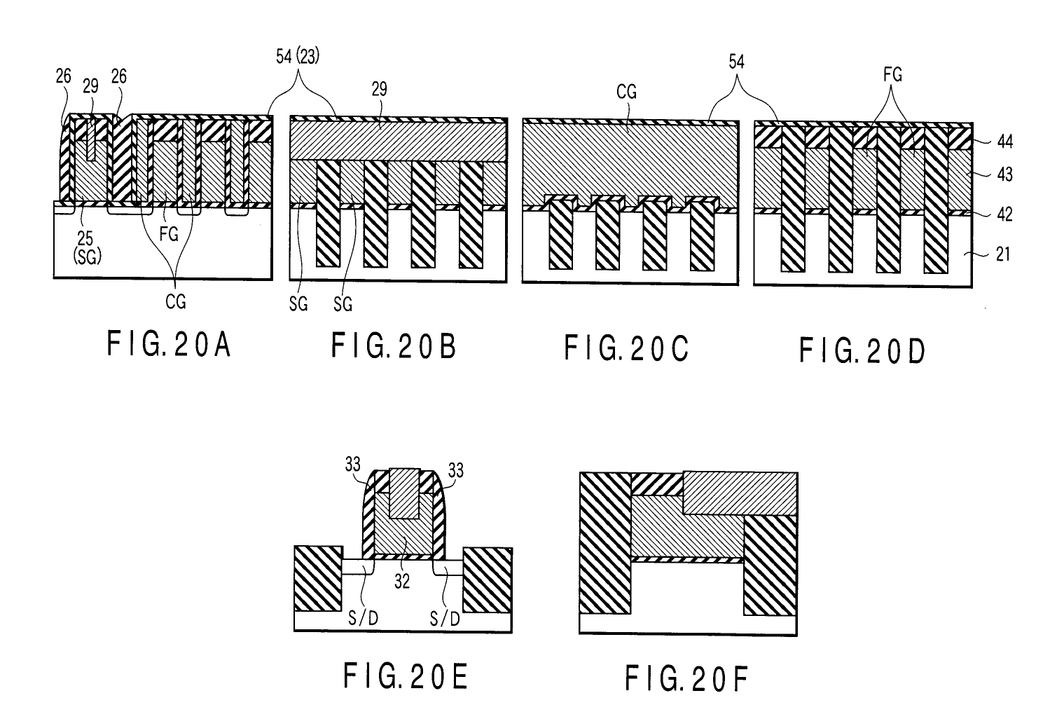

Subsequently, as shown in FIGS. 20A to 20F, a barrier film 54 (23) is formed on the entire surface of the memory cell array section. Further, an insulating film such as a silicon oxide film is formed on the entire surface of the memory cell array section and the peripheral circuit section. Thereafter, anisotropic etching such as RIE is conducted on the entire surface, and spacers 18 And 33 are formed on side walls of the select gate 25 (SG) and gate electrode 32.

Then, through conventional fabrication steps, an insulating layer 36 and a gate contact plug 39 are formed in the peripheral circuit section, and the semiconductor device shown in FIGS. 3, 6 and 7 is manufactured.

As has been described above, in the method of manufacturing the semiconductor device according to the present embodiment, the mask layer 50 is formed, and anisotropic etching is performed using the mask layer 50 as a mask. Thereby, the trenches 51-1 and 511 Are formed (FIGS. 16A to 16D and FIGS. 16E and 16F). The trenches 51-1 and 51-2 penetrate the mask layer 44, which is located on the formation region of the select gate line, i.e. the wiring layer 29, and the formation region of the contact line 35, and is provided in the polycrystalline silicon layer 43. Further, the polycrystalline silicon layer 52, for instance, is buried in the trenches 51-1 and 51-2. Thus, the wiring layer 29 is formed in the trench 51-1 and the contact line 35 is formed in the trench 51-2 (FIGS. 17A to 17F).

Therefore, the contact layer 29 and contact line 35 can be formed of the same material (e.g. polycrystalline silicon) at the same time. Advantageously, an increase in number of masks is prevented and the manufacturing cost can be reduced.

Further, a plurality of trenches 45 for device isolation are formed. The trenches 45 penetrate the mask layer 44, polycrystalline silicon layer 43 and gate insulation film 42, and reaches a point within the semiconductor substrate 21. The insulation film 46, such as a silicon oxide film, is buried in the trenches 45. Using the mask layer 44 as a stopper, the insulation film 46 is planarized by, e.g. CMP, and the device isolation film STI is formed (FIGS. 11A to 11F, FIGS. 12A to 12F).

Hence, the side wall of the gate electrode 32 in the gate width direction, the gate insulation film 31 (42) and a part of the substrate 21 are formed continuous in a self-alignment fashion. As a result, no fringe is formed on the gate electrode 32 in the gate width direction, and the distance between the transistors TR that are adjacent to each other in the gate width direction can be reduced, and microfabrication can advantageously be achieved. In addition, in many cases, the ratio of the area of the row decoder 13 including the peripheral circuit section to the entire area of the device is large. By the microfabrication of the peripheral circuit section, the peripheral circuit section can advantageously be integrated.

Through the above-described fabrication steps, the gate electrode 32 and sources/drains (S/D) are formed continuous in the gate length direction. Therefore, the distance W2 between the gate electrodes 32 of the transistors TR1 and TR2, TR3 and TR4, which are adjacent to each other in the gate width direction, can be set to be equal to the distance W1 between the sources/drains (S/D) of the transistors TR1 and TR2, TR3 and TR4, which are adjacent to each other in the gate width direction (FIG. 5 and FIG. 7).

### Second Embodiment

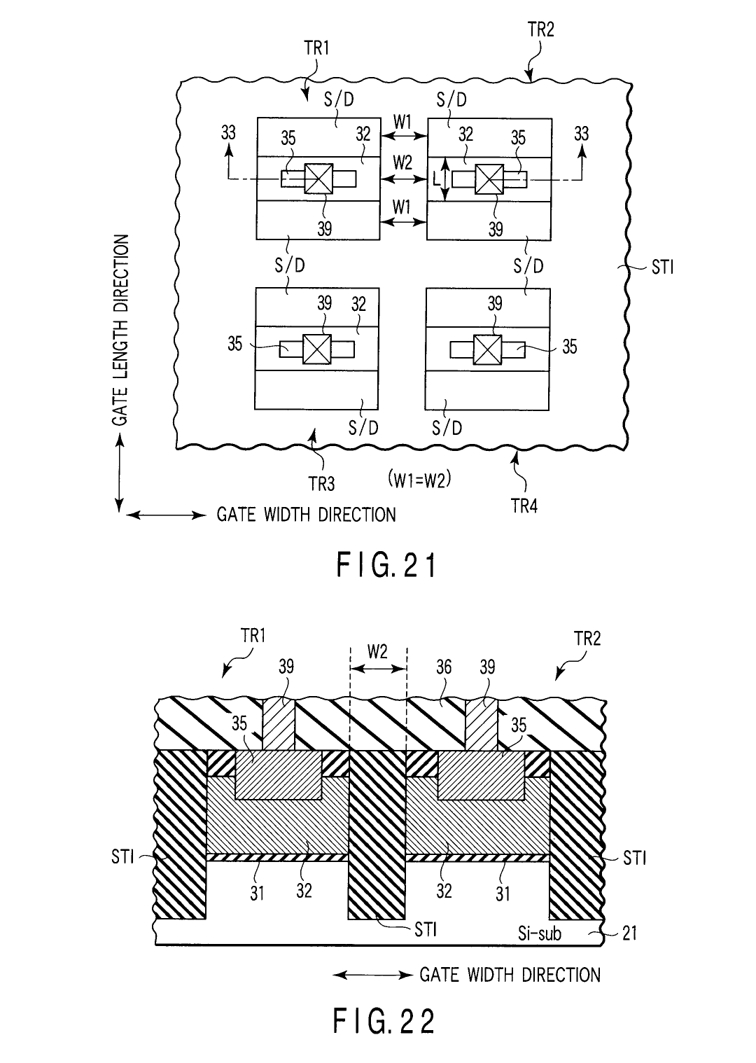

A semiconductor device according to a second embodiment of the present invention will now be described with reference to FIG. 21 and FIG. 22. A description of the parts that are common to those in the first embodiment is omitted. FIG. 21 is a plan view that schematically shows the semiconductor device of the second embodiment, and FIG. 22 is a cross-sectional view taken along line 22-22 in FIG. 21.

As is shown in FIGS. 21 and 22, a contact line 35 is formed to be buried in the gate electrode. Unlike the first embodiment, the contact line 35 is not extended in the width direction and is not provided on the device isolation insulating film STI.

Further, a gate contact plug 39 is provided on the contact line 35.

The method of manufacturing this semiconductor device is substantially the same as in the first embodiment, and a description thereof is omitted.

The above-described structure has the same advantage as in the first embodiment. In addition, in the semiconductor device of the second embodiment, the contact wiring layer 35 is buried in the gate electrode, and the wiring layer 35 is not extended in the gate width direction and not provided on the device isolation film STI.

Therefore, the area in the gate width direction can further be reduced, and microfabrication can advantageous be implemented.

The second embodiment is more advantageous when the dimension of the contact plug 39 is less than the channel length L of the gate electrode 32.

Furthermore, the contact plug 39 is located only on the gate electrode 32 in plan, and not located on the source/drain region. Therefore, such an advantage can be obtained that unintentional penetration of the contact plug 39 into the source/drain region can be prevented and the manufacturing yield is increased.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor integrated circuit device comprising an insulated-gate field-effect transistor, the insulated-gate field-effect transistor comprising:
a device isolation insulating film that is provided to extend from an inside of a semiconductor substrate and to project from an upper surface of the semiconductor substrate, and defines a device region on the semiconductor substrate;
a gate insulation film that is provided on the device region;
a gate electrode that is provided on the gate insulation film;
source/drain regions that are provided in the semiconductor substrate on both sides of the gate electrode;
an insulation layer that is provided on the gate electrode; and
a contact line that penetrates the insulation layer and is put in contact with the gate electrode,
wherein two opposed side walls of side walls of the gate electrode are put in contact with the device isolation insulating film, and a gate width of the gate electrode is defined by the device isolation insulating film.

2. The semiconductor integrated circuit device according to claim 1, further comprising a memory cell array including nonvolatile memory cell transistors arranged in a matrix, each of the nonvolatile memory cell transistors comprising:
a floating gate electrode that is provided on the semiconductor substrate via a gate insulation film;
source/drain regions that are provided in the semiconductor substrate on both sides of the floating gate electrode;
first and second control gates that are provided on both sides of the floating gate electrode and drive the floating gate electrode; and
an inter-gate insulation film that insulates the control gate electrode, the floating gate electrode and the source/drain regions,
wherein the insulated-gate field-effect transistor is used in a memory peripheral circuit that drives the memory cell array.

3. The semiconductor integrated circuit device according to claim 2, further comprising a select transistor that is provided in the memory cell array, the select transistor comprising:
a select gate electrode that is provided on the semiconductor substrate via a gate insulation film;
source/drain regions that are provided in the semiconductor substrate on both sides of the select gate electrode, one of the source/drain regions being shared with the source/drain region of the nonvolatile memory cell transistor, and the other of the source/drain regions being connected to a bit line or a source line; and
a select gate line that is put in contact with the select gate electrode and is formed of the same material as the contact line.

4. The semiconductor integrated circuit device according to claim 1, wherein a distance between the gate electrodes of the insulated-gate field-effect transistors, which are adjacent to each other in a gate width direction, is equal to a distance between the sources/drains of the insulated-gate field-effect transistors, which are adjacent to each other in the gate width direction

5. The semiconductor integrated circuit device according to claim 1, wherein the insulated-gate field-effect transistor is a high-voltage transistor that is used in a row decoder.

6. The semiconductor integrated circuit device according to claim 1, wherein a width of the contact line in a gate length direction is less than a width of the gate electrode in the gate length direction.

7. The semiconductor integrated circuit device according to claim 1, wherein the contact line and the gate electrode are formed of polycrystalline silicon.

8. The semiconductor integrated circuit device according to claim 7, wherein an impurity concentration in the contact line is less than an impurity concentration in the gate electrode.

9. The semiconductor integrated circuit device according to claim 1, wherein a surface of the insulation layer is continuous with a surface of the contact line.

10. A semiconductor integrated circuit device comprising an insulated-gate field-effect transistor, the insulated-gate field-effect transistor comprising:
a device isolation insulating film that is provided to extend from an inside of a semiconductor substrate and to project from an upper surface of the semiconductor substrate, and defines a device region on the semiconductor substrate;
a gate insulation film that is provided on the device region;
a gate electrode that is provided on the gate insulation film;
source/drain regions that are provided in the semiconductor substrate on both sides of the gate electrode;
an insulation layer that is provided on the gate electrode; and
a contact line that penetrates the insulation layer and is buried in the gate electrode,
wherein two opposed side walls of side walls of the gate electrode are put in contact with the device isolation insulating film, and a gate width of the gate electrode is defined by the device isolation insulating film.

11. The semiconductor integrated circuit device according to claim 10, further comprising a contact plug that is provided on the contact line.

12. The semiconductor integrated circuit device according to claim 10, further comprising a memory cell array including nonvolatile memory cell transistors arranged in a matrix, each of the nonvolatile memory cell transistors comprising:
a floating gate electrode that is provided on the semiconductor substrate via a gate insulation film;
source/drain regions that are provided in the semiconductor substrate on both sides of the floating gate electrode;
first and second control gates that are provided on both sides of the floating gate electrode and drive the floating gate electrode; and
an inter-gate insulation film that insulates the control gate electrode, the floating gate electrode and the source/drain regions,
wherein the insulated-gate field-effect transistor is used in a memory peripheral circuit that drives the memory cell array.

13. The semiconductor integrated circuit device according to claim 12, further comprising a select transistor that is provided in the memory cell array, the select transistor comprising:
a select gate electrode that is provided on the semiconductor substrate via a gate insulation film;
source/drain regions that are provided in the semiconductor substrate on both sides of the select gate electrode, one of the source/drain regions being shared with the source/drain region of the nonvolatile memory cell transistor, and the other of the source/drain regions being connected to a bit line or a source line; and
a select gate line that is put in contact with the select gate electrode and is formed of the same material as the contact line.

14. The semiconductor integrated circuit device according to claim 10, wherein a distance between the gate electrodes of the insulated-gate field-effect transistors, which are adjacent to each other in a gate width direction, is equal to a distance between the sources/drains of the insulated-gate field-effect transistors, which are adjacent to each other in the gate width direction

15. The semiconductor integrated circuit device according to claim 10, wherein the insulated-gate field-effect transistor is a high-voltage transistor that is used in a row decoder.

16. The semiconductor integrated circuit device according to claim 10, wherein a width of the contact line in a gate length direction is less than a width of the gate electrode in the gate length direction.

17. The semiconductor integrated circuit device according to claim 10, wherein the contact line and the gate electrode are formed of polycrystalline silicon.

18. The semiconductor integrated circuit device according to claim 17, wherein an impurity concentration in the contact line is less than an impurity concentration in the gate electrode.

19. The semiconductor integrated circuit device according to claim 10, wherein a surface of the insulation layer is continuous with a surface of the contact line.

20. A method of manufacturing a semiconductor integrated circuit device, comprising:
forming a gate insulation film on a semiconductor substrate;
forming a gate electrode on the gate insulation film;
forming an insulation layer on the gate electrode;
forming a first trench that defines a device region on the semiconductor substrate, the first trench penetrating the insulation layer, the gate electrode and the gate insulation film and reaching a point within the semiconductor substrate;
burying an insulator in the first trench, thereby forming a device isolation insulating film; and
forming a contact line that penetrates the device isolation insulating film and contacts the gate electrode.
